(19) United States
(12) Patent Application Publication
(10) Pub. No.: US 2021/0091275 A1
(43) Pub. Date: Mar. 25, 2021

(54) ELECTRONIC DEVICE AND MANUFACTURING METHOD OF ELECTRONIC DEVICE

(71) Applicant: Innolux Corporation, Miao-Li County (TW)

(72) Inventors: Jia-Yuan Chen, Miao-Li County (TW); Tsung-Han Tsai, Miao-Li County (TW); Kuan-Feng Lee, Miao-Li County (TW)

(73) Assignee: Innolux Corporation, Miao-Li County (TW)

(21) Appl. No.: 17/004,028

(22) Filed: Aug. 27, 2020

(30) Foreign Application Priority Data
Sep. 19, 2019 (CN) 201910885180.9

(51) Int. Cl. H01L 33/50; H01L 25/075; H01L 33/60; H01L 33/62; H01L 21/66; H01L 27/12; H01L 29/786

(52) U.S. Cl. CPC H01L 33/505; H01L 25/0753; H01L 33/60; H01L 33/62; H01L 2933/0066; H01L 27/1214; H01L 29/78633; H01L 2933/0041; H01L 2933/0058; H01L 22/22

(57) ABSTRACT

The disclosure provides an electronic device, including a substrate, an insulating layer, a light-emitting unit, and a light conversion element. The insulating layer is disposed on the substrate, and the insulating layer includes an opening and a sidewall surrounding the opening. The light-emitting unit is disposed in the opening. The light conversion element is disposed in the opening, and a height of the sidewall is greater than or equal to a height of the light conversion element. The electronic device of the embodiments of the disclosure can provide improved light emission effect or have a reduced thickness. The disclosure further provides a manufacturing method of an electronic device.

### CROSS-REFERENCE TO RELATED APPLICATION

This application claims the priority benefit of China application serial no. 201910885180.9, filed on Sep. 19, 2019. The entirety of the above-mentioned patent application is hereby incorporated by reference herein and made a part of this specification.

### BACKGROUND

### Technical Field

The disclosure relates to an electronic device and a manufacturing method of the electronic device.

### Description of Related Art

Electronic products have become indispensable in the modern society. With the rapid development of such electronic products, consumers have high expectations for the quality, functions, or prices of these products.

Therefore, the electronic products need to be improved by, for example, introducing materials having a wavelength conversion function. However, there are still some problems to be solved.

### SUMMARY

The disclosure is directed to an electronic device and a manufacturing method thereof which can provide improved light emission effect or can manufacture an electronic device reduced in thickness.

According to an embodiment of the disclosure, an electronic device includes a substrate, an insulating layer, a light-emitting unit, and a light conversion element. The insulating layer is disposed on the substrate, and the insulating layer includes an opening and a sidewall surrounding the opening. The light-emitting unit is disposed in the opening. The light conversion element is disposed in the opening, and a height of the sidewall is greater than or equal to a height of the light conversion element.

According to an embodiment of the disclosure, a manufacturing method of an electronic device includes at least steps below. A substrate is provided. An insulating layer is formed on the substrate. The insulating layer includes an opening and a sidewall surrounding the opening. A light-emitting unit is disposed in the opening. A light conversion element is disposed in the opening, and a height of the sidewall is greater than or equal to a height of the light conversion element.

In summary of the above, in the electronic device according to the embodiments of the disclosure, the light conversion element and the light-emitting unit are disposed in the opening surrounded by the sidewall of the insulating layer. Therefore, the thickness of the electronic device of the embodiments of the disclosure can be reduced. In some embodiments, the light conversion element may surround the light-emitting unit to utilize the light laterally emitted by the light-emitting unit, so that the light-emitting area of the electronic device can be expanded to mitigate the phenomenon of light concentration. On the whole, the light-emitting device of the embodiments of the disclosure can provide improved light emission effect and improve the quality of the electronic device.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1G are schematic views showing a partial manufacturing process of an electronic device according to an embodiment of the disclosure.

FIG. 2A is a schematic top view showing an electronic device according to another embodiment of the disclosure.

FIG. 2B is a schematic cross-sectional view showing the electronic device of FIG. 2A.

FIG. 3 is a schematic cross-sectional view showing an electronic device according to another embodiment of the disclosure.

FIG. 4 is a schematic cross-sectional view showing an electronic device according to still another embodiment of the disclosure.

FIG. 5 is a schematic cross-sectional view showing an electronic device according to still another embodiment of the disclosure.

FIG. 6 is a schematic cross-sectional view showing an electronic device according to still another embodiment of the disclosure.

FIG. 7 is a schematic cross-sectional view showing an electronic device according to still another embodiment of the disclosure.

FIG. 8 is a schematic cross-sectional view showing an electronic device according to still another embodiment of the disclosure.

FIG. 9 is a schematic cross-sectional view showing an electronic device according to still another embodiment of the disclosure.

### DESCRIPTION OF THE EMBODIMENTS

“A structure (or layer, unit, substrate, etc.) being located on/above another structure (or layer, unit, substrate, etc.)” as described in the disclosure may mean that the two structures are adjacent and directly connected, or may mean that the two structures are adjacent but are not directly connected. “Not being directly connected” means that at least one intermediate structure (or intermediate layer, intermediate unit, intermediate substrate, intermediate interval, etc.) is present between the two structures, where the lower surface of one structure is adjacent or directly connected to the upper surface of the intermediate structure, the upper surface of the other structure is adjacent or directly connected to the lower surface of the intermediate structure, and the intermediate structure may be composed of a single-layer or multi-layer physical structure or non-physical structure and is not specifically limited herein. In the disclosure, when one structure is disposed “on” another structure, it may mean that the one structure is “directly” on the another structure, or may mean that the one structure is “indirectly” on the another structure (i.e., at least one other structure is interposed between the one structure and the another structure).

Electrical connection or coupling as described in the disclosure may both refer to direct connection or indirect connection. In the case of direct connection, the terminal points of two units on the circuit are directly connected or are connected to each other via a conductor line segment. In the case of indirect connection, a switch, a diode, a capacitor, an inductor, a resistor, another suitable unit, or a combination of the above units is present between the terminal points of two units on the circuit. However, the disclosure is not limited thereto.

In the disclosure, the thickness, length, or width may be measured by an optical microscope, and the thickness may be measured according to a cross-sectional image in an electron microscope, but the disclosure is not limited thereto. In addition, there may be a certain error between any two values or directions used for comparison. If a first value is equal to a second value, it is implied that there may be an error of about 10% between the first value and the second value; if a first direction is perpendicular to a second direction, the angle between the first direction and the second direction may be 80 degrees to 100 degrees; and if the first direction is parallel to the second direction, the angle between the first direction and the second direction may be 0 degrees to 10 degrees.

Reference will now be made in detail to the exemplary embodiments of the disclosure, examples of which are illustrated in the accompanying drawings. Whenever possible, the same reference numerals are used to represent the same or similar parts in the accompanying drawings and description.

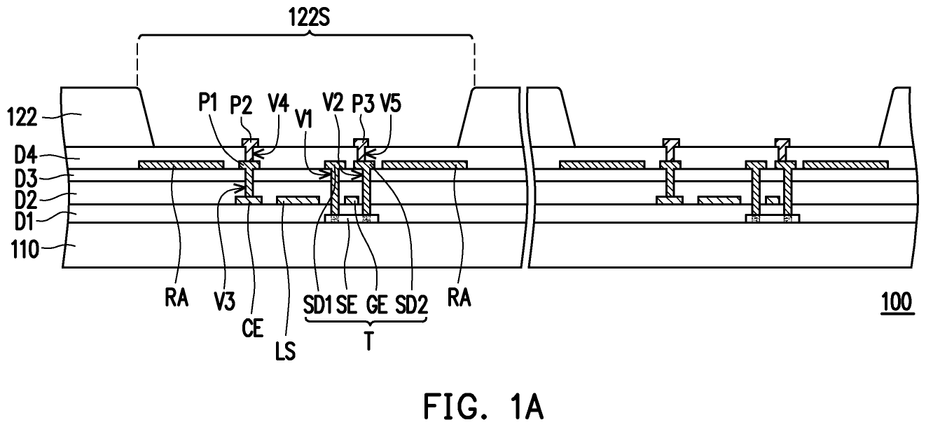

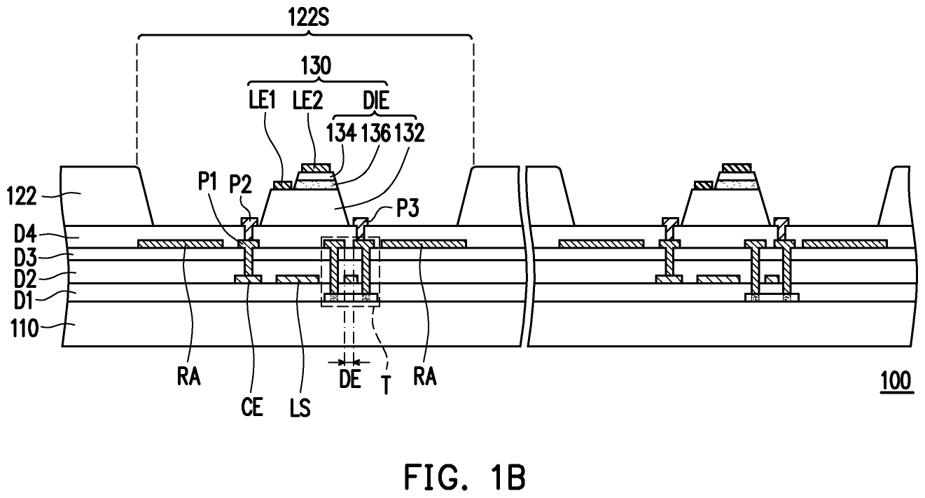

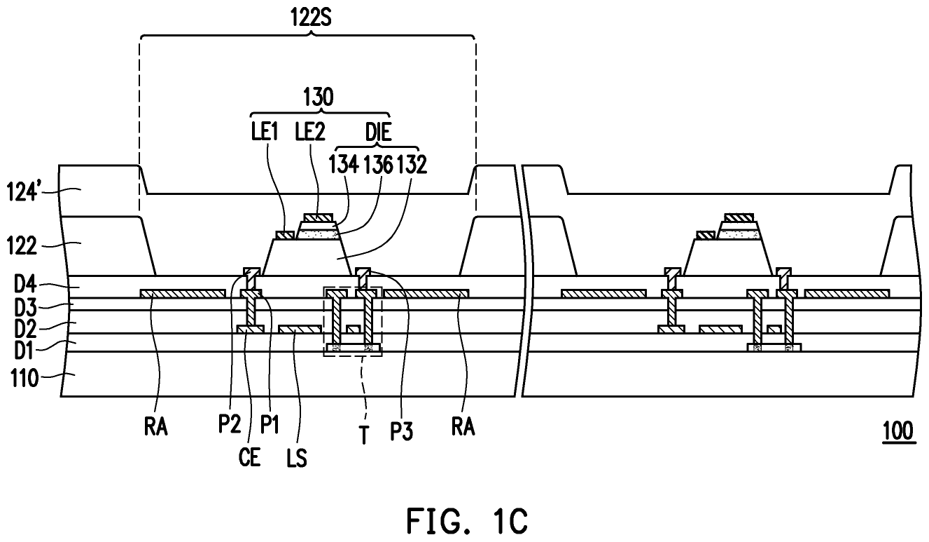

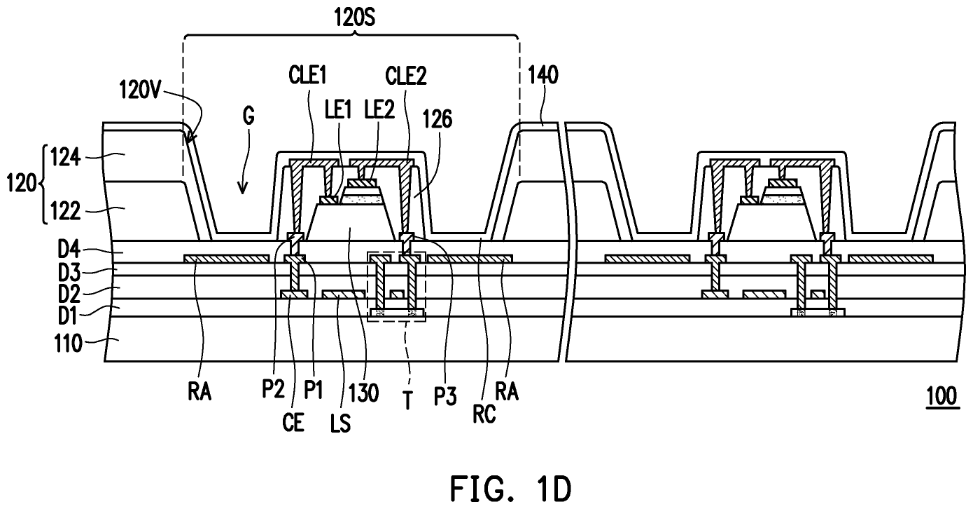

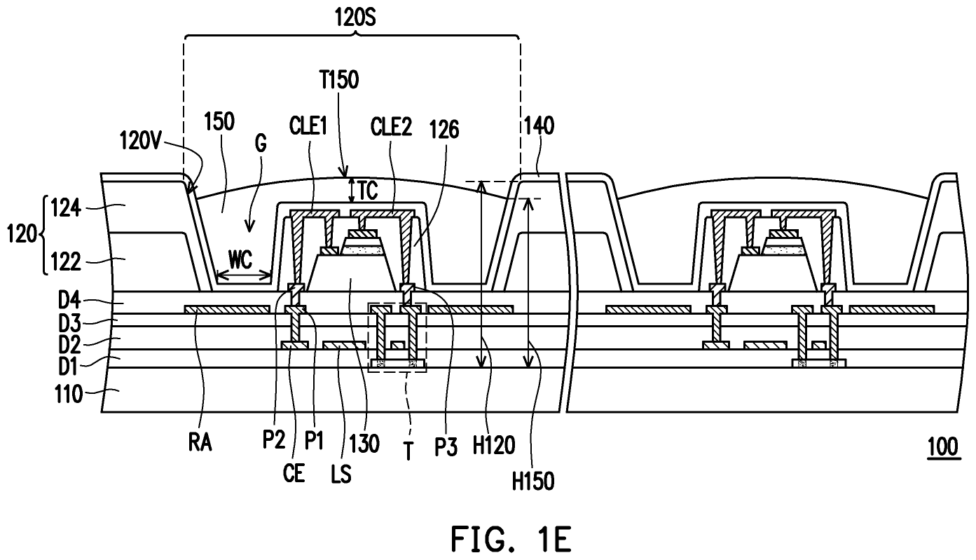

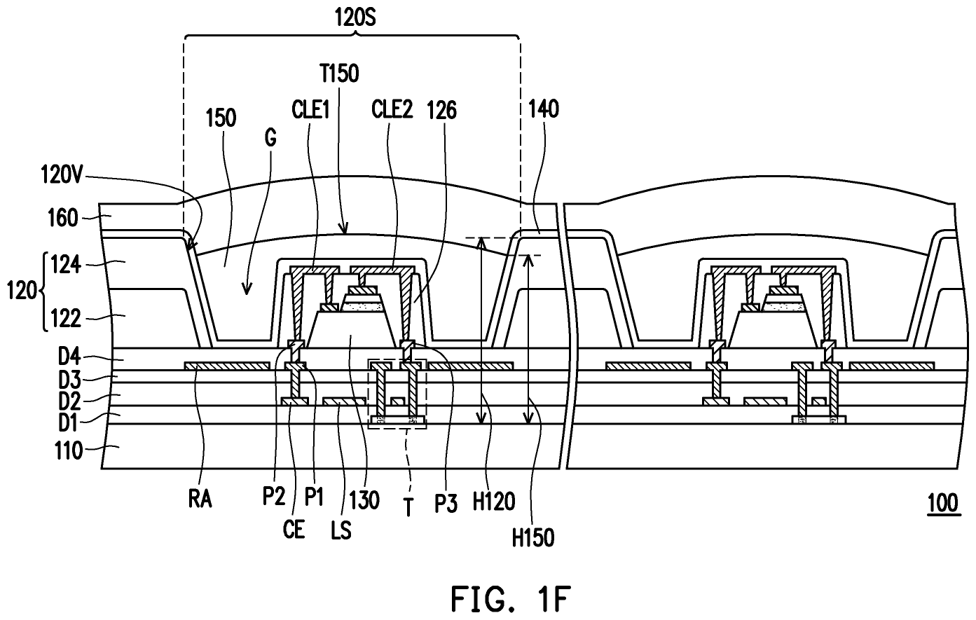

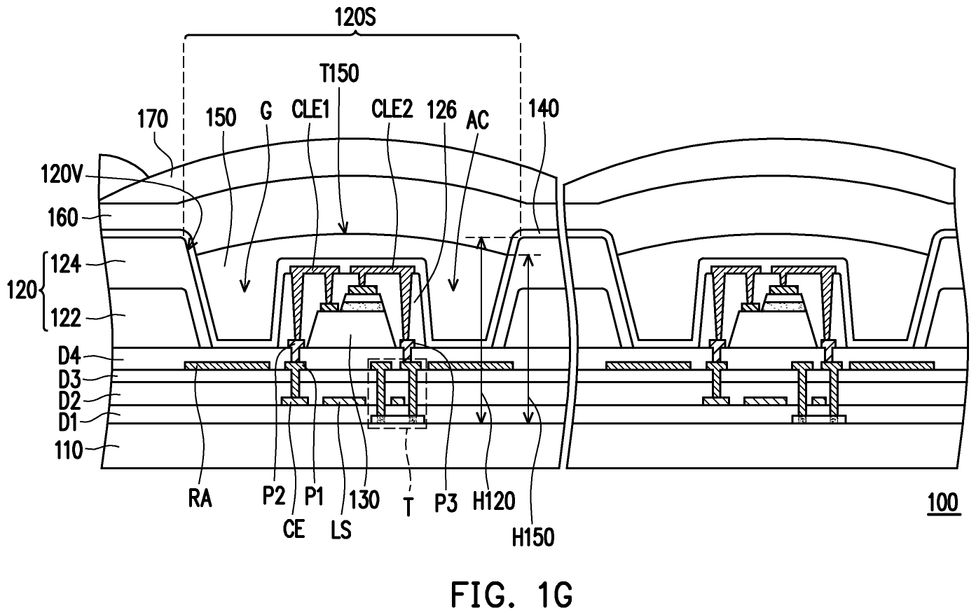

FIG. 1A to FIG. 1G are schematic views showing a partial manufacturing process of an electronic device according to an embodiment of the disclosure. It is understood that, according to some embodiments, additional operation steps may be provided before, during, and/or after performance of the manufacturing method of the electronic device of the disclosure. According to some embodiments, some of the operation steps as described herein may be replaced or omitted. According to some embodiments, the order of the operation steps is interchangeable.

In FIG. 1A, a substrate 110 is provided. The material of the substrate 110 may include glass, quartz, sapphire, ceramic, polyimide (PI), a liquid-crystal polymer (LCP) material, polycarbonate (PC), photo sensitive polyimide (PSPI), polyethylene terephthalate (PET), another suitable material, or a combination of the above materials but is not limited thereto. In the present embodiment, an active unit T (e.g., a thin film transistor, but is not limited thereto) may be disposed on the substrate 110. In an embodiment, the active unit T may include a semiconductor layer SE, a gate GE, a first source/drain SD1, and a second source/drain SD2. The semiconductor layer SE may be disposed on the substrate 110, the gate GE may overlap with the semiconductor layer SE along the normal direction of the substrate 110, and the semiconductor layer SE may be located between the gate GE and the substrate 110. The first source/drain SD1 and the second source/drain SD2 may be disposed on two sides of the gate GE and may be respectively in contact with different parts of the semiconductor layer SE. A reflective layer RA may be disposed adjacent to the active unit T. The semiconductor layer SE may include an amorphous semiconductor (e.g., amorphous silicon), a polycrystalline semiconductor (e.g., polycrystalline silicon), an organic semiconductor material, a metal oxide (e.g., indium gallium zinc oxide), another suitable material, or a combination of the above materials and is not limited thereto. In some embodiments, the material of the semiconductor layer SE of at least one active unit T in the electronic device may be different from the material of the semiconductor layer SE of other active units T. The materials of the gate GE, the first source/drain SD1, and the second source/drain SD2 may include an electrically conductive material such as copper (Cu), silver (Ag), tin (Sn), aluminum (Al), molybdenum (Mo), tungsten (W), gold (Au), chromium (Cr), nickel (Ni), platinum (Pt), titanium (Ti), a copper alloy, a silver alloy, a tin alloy, an aluminum alloy, a molybdenum alloy, a tungsten alloy, a gold alloy, a chromium alloy, a nickel alloy, a platinum alloy, a titanium alloy, another suitable electrically conductive material, or a combination of the above materials but are not limited thereto.

In order to form the required electrical connections, a plurality of dielectric layers D1 to D4, a common line CE, a connection electrode P1, a connection electrode P2, a connection electrode P3, and/or other electronic units may be disposed on the substrate 110. The reflective layer RA may be disposed on the substrate 110 to provide the required light reflection, and/or a light shielding layer LS may be disposed on the substrate 110 to provide light shielding effect. The dielectric layer D1 may cover the semiconductor layer SE, and the gate GE is disposed on the dielectric layer D1. In other words, the dielectric layer D1 is disposed between the gate GE and the semiconductor layer SE to serve as a gate dielectric layer. In the present embodiment, the common line CE and the light shielding layer LS may also be disposed on the dielectric layer D1 but are not limited thereto. The light shielding layer LS may be disposed adjacent to the active unit T. In an embodiment, the gate GE, the common line CE, and the light shielding layer LS may be units manufactured in a same film layer but are not limited thereto. The dielectric layer D2 may be disposed on the gate GE, the common line CE, and the light shielding layer LS, and the dielectric layer D3 may be disposed on the dielectric layer D2. The reflective layer RA, the connection electrode P1, the first source/drain SD1, and the second source/drain SD2 may be disposed on the dielectric layer D3 but are not limited thereto. A through hole V1 and a through hole V2 may penetrate through the dielectric layer D1, the dielectric layer D2, and the dielectric layer D3 to extend to the semiconductor layer SE, and a through hole V3 may penetrate through the dielectric layer D2 and the dielectric layer D3 to extend to the common line CE. The first source/drain SD1 and the second source/drain SD2 may be disposed in the through hole V1 and the through hole V2 to be in contact with the semiconductor layer SE via the through hole V1 and the through hole V2. The connection electrode P1 may be filled into the through hole V3 to be in contact with the common line CE via the through hole V3. The dielectric layer D4 is disposed on the dielectric layer D3. The dielectric layer D4 is disposed on the reflective layer RA, the connection electrode P1, the first source/drain SD1, and the second source/drain SD2. The reflective layer RA, the connection electrode P1, the first source/drain SD1, and the second source/drain SD2 may be manufactured using a same film layer. In other words, the reflective layer RA, the connection electrode P1, the first source/drain SD1, and the second source/drain SD2 may have the same material. The connection electrode P2 and the connection electrode P3 are disposed on the dielectric layer D4. A through hole V4 and a through hole V5 respectively penetrate through the dielectric layer D4 to extend to the connection electrode P1 and the second source/drain SD2. The connection electrode P2 may be disposed in the through hole V4 to be in contact with the connection electrode P1. The connection electrode P3 may be disposed in the through hole V5 to be in contact with the second source/drain SD2. In an embodiment, at least one of the dielectric layers D1 to D4 may include a multi-layer structure but is not limited thereto. It is noted that, although the above description is based on a top-gate active unit as an example, the active unit T in the disclosure may also include a bottom-gate active unit, a dual-gate active unit, or another suitable active unit.

Referring to FIG. 1A again, a first sub-layer 122 may be formed on the substrate 110. Specifically, the first sub-layer 122 may be formed on the dielectric layer D4, and the first sub-layer 122 is patterned to have a sub-layer opening 122S. The manufacturing method of the first sub-layer 122 includes, for example, forming a full-layer insulating material layer on the substrate 110 and patterning the insulating material layer by a lithography process or a lithography-etching process to form the first sub-layer 122. The formation method of the full-layer insulating material layer may include coating, deposition, or the like but is not limited thereto. Herein, the material for forming the first sub-layer 122 may include a perfluoroalkoxy polymer resin (PFA), a polymer film on array, a fluoroelastomer, another suitable material, or a combination of the above materials but is not limited thereto. The width of the sub-layer opening 122S in a cross-section may, for example, increase as the distance from the substrate 110 increases but is not limited thereto.

Next, referring to FIG. 1B, a light-emitting unit 130 may be disposed on the substrate 110. In the present embodiment, the light-emitting unit 130 may be disposed in the sub-layer opening 122S defined by the first sub-layer 122. In an embodiment, the light shielding layer LS may, for example, overlap with the light-emitting unit 130 along the normal direction of the substrate 110 and can shield the light emitted by the light-emitting unit 130 toward the substrate 110. In the disclosure, unless otherwise specified, “overlap” may include “fully overlap” and “partially overlap”. For example, the orthographic projection area of the light-emitting unit 130 on the substrate 110 may overlap with the orthographic projection area of the light shielding layer LS on the substrate 110. In the present embodiment, the light-emitting unit 130 may include a light-emitting diode, an organic light-emitting diode (OLED), quantum dots (QD), a fluorescence material, a phosphor material, a micro light-emitting diode/mini light-emitting diode, a quantum dot light-emitting diode (QLED/QDLED), another suitable material, or a combination of the above materials, but the disclosure is not limited thereto. For example, the light-emitting unit 130 may include a first semiconductor layer 132, a second semiconductor layer 134, an active layer 136, a first electrode LE1, and a second electrode LE2 but is not limited thereto. The active layer 136 may be disposed between the first semiconductor layer 132 and the second semiconductor layer 134 to form a stack structure DIE. The first electrode LE1 may be connected to the first semiconductor layer 132, and the second electrode LE2 may be connected to the second semiconductor layer 134. The first electrode LE1 and the second electrode LE2 may be located on a first side of the stack structure DIE, the dielectric layer D4 may be located on a second side of the stack structure DIE, and the first side and the second side are two opposite sides. However, in other embodiments, the arrangement direction of the light-emitting unit 130 and the electrode configuration position of the light-emitting unit 130 may be adjusted depending on different designs and are not limited to the structure of FIG. 1B. In an embodiment, a distance DE may be present between the light-emitting unit 130 and the connection electrode P2 and/or between the light-emitting unit 130 and the connection electrode P3 to reduce the probability of leakage. The range of the distance DE may vary considering the routing process or the light-emitting unit transfer process. Therefore, the distance DE may be in the range of 0.1 μm to 10 μm (0.1 μm≤DE≤10 μm), such as 0.5 μm, 1 μm, 3 μm, 5 μm, or 7 μm, but is not limited thereto.

Referring to FIG. 1C, after the light-emitting unit 130 is disposed on the substrate 110, an insulating material layer 124′ may be formed on the substrate 110. The insulating material layer 124′ may cover the light-emitting unit 130, the first sub-layer 122, and the dielectric layer D4, and the insulating material layer 124′ fills in the sub-layer opening 122S. The material of the insulating material layer 124′ may include a perfluoroalkoxy polymer resin (PFA), a polymer film on array, a fluoroelastomer, another suitable material, or a combination of the above materials but is not limited thereto.

Next, referring to FIG. 1C and FIG. 1D, the insulating material layer 124′ may be patterned to form a second sub-layer 124 such that the second sub-layer 124 is disposed on the first sub-layer 122. The first sub-layer 122 and the second sub-layer 124 may form an insulating layer 120. The insulating layer 120 has an opening 120S, and a sidewall 120V of the insulating layer 120 may define the opening 120S. In the disclosure, unless otherwise specified, “surround” may include “fully surround” and “partially surround”. The light-emitting unit 130 may be disposed in the opening 120S. In the present embodiment, the second sub-layer 124 may cover the top surface of the first sub-layer 122 and also cover the sidewall of the first sub-layer 122. The opening 120S may have a non-fixed width perpendicular to the normal direction of the substrate 110. For example, the width of the opening 120S further away from the substrate 110 may be greater than the width of the opening 120S closer to the substrate 110. In other embodiments, the second sub-layer 124 may selectively cover only the top surface of the first sub-layer 122 without covering the sidewall of the first sub-layer 122.

A portion of the insulating material layer 124′ may encapsulate the light-emitting unit 130 to form an encapsulating layer 126. However, in other embodiments, it is possible that the encapsulating layer 126 is not formed by patterning the insulating material layer 124′ but is manufactured through another method. Therefore, the material of the encapsulating layer 126 may be the same as or different from that of the second sub-layer 124. In the present embodiment, a connection electrode CLE1 and a connection electrode CLE2 may be disposed on the encapsulating layer 126. The connection electrode CLE1 may be connected between the first electrode LE1 of the light-emitting unit 130 and the connection electrode P2 on the substrate 110, and the connection electrode CLE2 may be connected between the second electrode LE2 of the light-emitting unit 130 and the connection electrode P3 on the substrate 110. In some embodiments, the light-emitting unit 130, the encapsulating layer 126, and the connection electrodes CLE1 and CLE2 may be manufactured through other methods and are not limited to the above manufacturing methods. The width perpendicular to the normal direction of the substrate 110 of the opening 120S may be greater than the width of the light-emitting unit 130 and may also be greater than the width of the encapsulating layer 126, so a gap G may be present between the encapsulating layer 126 and the insulating layer 120. As can be seen from FIG. 1D, the orthographic projection area of the reflective layer RA on the substrate 110 and the orthographic projection area of the gap G on the substrate 110 are overlapped.

In addition, in the present embodiment, a capping layer 140 may be selectively further formed on the substrate 110 to protect the connection electrode CLE1 and the connection electrode CLE2. For example, in addition to covering the connection electrode CLE1 and the connection electrode CLE2, the capping layer 140 may further cover the insulating layer 120. Moreover, the capping layer 140 may extend in the gap G between the insulating layer 120 and the light-emitting unit 130. However, in other embodiments, the capping layer 140 may be omitted, or the capping layer 140 may be disposed to cover only the connection electrode CLE1 and the connection electrode CLE2, but the disclosure is not limited thereto. The material of the capping layer 140 may include silicon oxide, silicon nitride, silicon oxynitride, hafnium oxynitride, or a combination thereof. In an embodiment, the capping layer 140 may be a multi-layer structure, and the multi-layer structure may include different material layers. The thickness of the capping layer 140 may be in the range of 0.05 μm to 1 μm (0.05 μm≤thickness≤1 μm), such as 0.1 μm, 0.3 μm, or 0.7 μm.

Next, as shown in FIG. 1E, a light conversion element 150 may be formed on the substrate 110, and the light conversion element 150 may be disposed in the opening 120S of the insulating layer 120. The material of the light conversion element 150 may include a quantum dot (QD) material, a fluorescence material, a phosphor material, another suitable material, or a combination of the above materials but is not limited thereto. Specifically, the formation method of the light conversion element 150 includes, for example, first filling a light conversion material into the opening 120S, and then curing the light conversion material in the opening 120S to form the light conversion element 150. Accordingly, the light conversion element 150 and the light-emitting unit 130 may both be disposed in the opening 120S defined by the insulating layer 120. At least a portion of the light conversion element 150 may be located in the gap G between the light-emitting unit 130 and the insulating layer 120. For example, the light conversion element 150 may be located around the light-emitting unit 130 and may surround the light-emitting unit 130. The light conversion element 150 may have a curved top surface T150. In an embodiment, the center of the top surface T150 of the light conversion element 150 may be further away from the substrate 110 than the periphery of the top surface T150 along the normal direction of the substrate 110, but the disclosure is not limited thereto. Moreover, the orthographic projection area of the light conversion element 150 on the substrate 110 and the orthographic projection area of the reflective layer RA on the substrate 110 are overlapped.

The insulating layer 120 may define a plurality of openings 120S on the substrate 110. In that case, if the material of the light conversion element 150 is a quantum dot material, the materials of the light conversion elements 150 in two adjacent openings 120S may be different. The material of the light conversion element 150 may include a red light quantum dot material, a green light quantum dot material, a blue light quantum dot material, another suitable material, or a combination of the above materials but is not limited thereto. For example, the light conversion element 150 in one of the openings 120S may selectively include a red light quantum dot material, and the light conversion element 150 in an adjacent opening 120S may include a green light quantum dot material, but the disclosure is not limited thereto. In the present embodiment, the sidewall 120V of the insulating layer 120 may have a height H120 along the normal direction of the substrate 110 sufficient to reduce mutual contamination of materials of the light conversion elements 150 in the adjacent openings 120S. Therefore, the design of the present embodiment can improve the quality of the light conversion element 150. In the present embodiment, the height H120 of the sidewall 120V may be, for example, greater than or equal to a height H150 of the light conversion element 150 along the normal direction of the substrate 110. Here, the so-called height H120 of the sidewall 120V may be the maximum distance between the sidewall 120V of the insulating layer 120 and the surface of the substrate 110 in the cross-sectional structure. Meanwhile, the so-called height H150 of the light conversion element 150 may be regarded as the maximum distance from the position at which the light conversion element 150 is in contact with the capping layer 140 on the insulating layer 120 to the surface of the substrate 110. When the capping layer 140 is omitted, the height H150 of the light conversion element 150 may be the maximum distance from the light conversion element 150 to the surface of the substrate 110. In an embodiment, the light conversion element 150 on the light-emitting unit 130 has a thickness TC along the normal direction of the substrate 110, and the thickness TC may be the maximum thickness of the portion of the light conversion element 150 that overlaps with the light-emitting unit 130 along the normal direction of the substrate 110. The thickness TC may be in the range of 0.1 μm to 4 μm (0.1 μm≤TC≤4 μm). The light conversion element 150 has a width WC in the gap G along a direction perpendicular to the normal direction of the substrate 110, and the width WC may be the minimum width of the light conversion element 150 in the gap G. The width WC may be in the range of 1 μm to 5 μm (1 μm≤WC≤5 μm). The ratio (TC/WC) between the thickness TC and the width WC may be in the range of 0.25 to 50 (0.25≤TC/WC≤50), such as 0.5, 1, 5, 10, 20, or 30, but is not limited thereto.

Next, as shown in FIG. 1F, a protective layer 160 is further formed on the structure shown in FIG. 1E. The protective layer 160 may be disposed on a unit located on the substrate 110, for example, disposed on the insulating layer 120, the light-emitting unit 130, and the light conversion element 150. The material of the protective layer 160 may include a perfluoroalkoxy polymer resin (PFA), a polymer film on array, a fluoroelastomer, or another material but is not limited thereto. The protective layer 160 may, for example, have the effect of inhibiting the intrusion of moisture but is not limited thereto. Thereafter, as shown in FIG. 1G, a light filter layer 170 may be further disposed on the protective layer 160 to form an electronic device 100. In an embodiment, the light filter layer 170 may allow only red light, green light, blue light, yellow light, or a light of a specific wavelength range to pass but is not limited thereto. In FIG. 1G, the electronic device 100 may include the substrate 110, the insulating layer 120, the light-emitting unit 130, the capping layer 140, the light conversion element 150, the protective layer 160, and the light filter layer 170. In an embodiment, the light filter layer 170 may extend into the opening 120S, for example, by reducing the thickness of the light conversion element 150, reducing the thickness of the protective layer 160, and/or increasing the height H120.

Units such as the active unit T, the common line CE, the light shielding layer LS, the reflective layer RA, the connection electrode P1, the connection electrode P2, and the connection electrode P3 may be disposed on the substrate 110. These units may be formed of different conductive layers, semiconductor layers, etc. Also, the dielectric layer D1 to the dielectric layer D4 separating the different conductive layers may be disposed on the substrate 110.

The insulating layer 120 may be disposed on the substrate 110. The insulating layer 120 includes the opening 120S and the sidewall 120V surrounding the opening 120S. The insulating layer 120 may be a multi-layer stack layer, but is not limited thereto. In other embodiments, the insulating layer 120 may be a single-layer structure, double layer structure, or a multi-layer stack layer structure of three or more than three layers. In the present embodiment, the insulating layer 120 may include the first sub-layer 122 and the second sub-layer 124, and the materials of the first sub-layer 122 and the second sub-layer 124 may be the same or different. Moreover, the thickness of the first sub-layer 122 may be greater than, equal to, or less than the thickness of the second sub-layer 124. The materials of the first sub-layer 122 and the second sub-layer 124 may respectively include an organic insulating material, an inorganic insulating material, or a combination thereof.

The first sub-layer 122 may be disposed on the substrate 110 and located on the dielectric layer D4. The second sub-layer 124 may be disposed on the first sub-layer 122. For example, the first sub-layer 122 may be located between the second sub-layer 124 and the substrate 110. The second sub-layer 124 may be disposed on the top surface and the sidewall of the first sub-layer 122, so the second sub-layer 124 may substantially encapsulate the first sub-layer 122. After the second sub-layer 124 is disposed, the first sub-layer 122 may be more stably disposed on the substrate 110 or is less likely to peel off, which helps to improve the reliability of the electronic device 100. For example, in some embodiments, the material of the dielectric layer D4 may include an inorganic insulating material, and the material of the first sub-layer 122 may include an organic insulating material. Due to the difference in material properties, the adhesion properties of the first sub-layer 122 and the dielectric layer D4 are not necessarily stable, and the first sub-layer 122 may peel off from the dielectric layer D4. Therefore, disposing the second sub-layer 124 can improve such an issue. However, in other embodiments, the second sub-layer 124 may selectively not cover the sidewall of the first sub-layer 122 such that the sidewall of the first sub-layer 122 contacts other layers, such as the capping layer 140.

The light-emitting unit 130 may include a light-emitting diode. The light emitted by the light-emitting unit 130 may be irradiated laterally toward the adjacent light conversion element 150. In FIG. 1G, one single light-emitting unit 130 is represented by only one single light-emitting diode. However, in other embodiments, the light-emitting unit 130 may include multiple light-emitting diodes, such as two, three, or four light-emitting diodes but is not limited thereto. Moreover, the light-emitting unit 130 may include a light-emitting diode package which has already been packaged. The light emitted by the light-emitting unit 130 may include white light, blue light, green light, red light, and/or ultraviolet light but is not limited thereto. In addition, the light-emitting unit 130 may be encapsulated by the encapsulating layer 126. In some embodiments, the encapsulating layer 126 may be selectively manufactured together with the second sub-layer 124. Therefore, the material of the encapsulating layer 126 may be the same as that of the second sub-layer 124, but is not limited thereto.

The encapsulating layer 126 may be disposed on the sidewall and the top surface (the surface of the light-emitting unit 130 away from the substrate 110) of the light-emitting unit 130 to protect the light-emitting unit 130. In other embodiments, the encapsulating layer 126 may also be omitted, or the encapsulating layer 126 and the light-emitting unit 130 may be a pre-made package. Therefore, the material of the encapsulating layer 126 may also be different from that of the second sub-layer 124. The connection electrode CLE1 and/or the connection electrode CLE2 may be disposed on the encapsulating layer 126 to electrically connect the light-emitting unit 130 to the connection electrode P2 and the connection electrode P3 disposed on the substrate 110. The capping layer 140 may cover the second sub-layer 124 of the insulating layer 120 and the encapsulating layer 126. The thickness of the capping layer 140 may be in the range of 0.05 μm to 1 μm (0.05 μm≤thickness≤1 μm), such as 0.1 μm, 0.3 μm, 0.5 μm, or 0.7 μm, but is not limited thereto. The capping layer 140 may cover the connection electrode CLE1 and the connection electrode CLE2 to protect the connection electrode CLE1 and the connection electrode CLE2. However, in other embodiments, the capping layer 140 may also be omitted. In addition, it is possible that the light-emitting unit 130 is not limited to be connected to the connection electrode P2 and the connection electrode P3 on the substrate 110 via the connection electrode CLE1 and the connection electrode CLE2, but is connected to the connection electrode P2 and the connection electrode P3 on the substrate 110 by other means.

The orthographic projection area of the encapsulating layer 126 on the substrate 110 may be smaller than the orthographic projection area of the opening 120S on the substrate 110, so the gap G may be present between the insulating layer 120 and the encapsulating layer 126. The light conversion element 150 may be disposed in the opening 120S of the insulating layer 120, and the light conversion element 150 is at least partially disposed between the insulating layer 120 and the encapsulating layer 126. The height H120 of the sidewall 120V of the insulating layer 120 is, for example, greater than or equal to the height H150 of the light conversion element 150 along the normal direction of the substrate 110. As can be seen from FIG. 1G, the light conversion element 150 may be disposed adjacent to the light-emitting unit 130. For example, the light conversion element 150 may surround the light-emitting unit 130. Specifically, the light conversion element 150 may fully surround the periphery of the light-emitting unit 130, or may surround only a portion of the periphery of the light-emitting unit 130. The light conversion element 150 may have a curved top surface such as a lens-shaped top surface, which helps to improve light emission uniformity.

The material of the light conversion element 150 may include a fluorescence material, a phosphor material, a quantum dot material, another suitable material, or a combination of the above materials, but is not limited thereto. The wavelength range of the light emitted by the light-emitting unit 130 may, for example, excite the light conversion element 150. When the material of the light conversion element 150 is a quantum dot material, the light conversion element 150 may emit red light, green light, blue light, or a light of another color based on the selection of the quantum dot material (e.g., adjustment of the particle size). Accordingly, the light conversion element 150 disposed adjacent to the light-emitting unit 130 can widen the light-emitting area of the electronic device 100, which helps to improve the phenomenon of disuniform light emission effect caused by a concentrated light-emitting area.

In the present embodiment, the reflective layer RA is disposed on the substrate 110, and the orthographic projection area of the reflective layer RA on the substrate 110 may be adjacent to the orthographic projection area of the light-emitting unit 130 on the substrate 110. For example, the orthographic projection area of the reflective layer RA on the substrate 110 may surround the orthographic projection area of the light-emitting unit 130 on the substrate 110. The orthographic projection area of the reflective layer RA on the substrate 110 and the orthographic projection area of the light conversion element 150 surrounding the light-emitting unit 130 on the substrate 110 are overlapped. Accordingly, the reflective layer RA can reflect the light emitted by the light conversion element 150, so that the light is emitted away from the substrate 110. This helps to improve the light extraction efficiency and improve the situation in which the light traveling toward the substrate 110 cannot be utilized. The material of the reflective layer RA may include a metal material or a Bragg reflection structure formed by stacking a plurality of material layers, but is not limited thereto. In some embodiments, at least two of the reflective layer RA, the first source/drain SD1, and the second source/drain SD2 may be manufactured in the same film layer. Therefore, the material of the reflective layer RA may be the same as the materials of the first source/drain SD1 and the second source/drain SD2 and may be, for example, a metal material.

The protective layer 160 may be disposed on the insulating layer 120 and the light conversion element 150. The protective layer 160 may have the effect of inhibiting the intrusion of moisture and reducing deterioration or damage to the light conversion element 150 resulting from the intruding moisture. The light filter layer 170 is disposed on the protective layer 160. The orthographic projection area of the light filter layer 170 on the substrate 110 and the orthographic projection area of the corresponding light conversion element 150 on the substrate 110 are overlapped. The material of the light filter layer 170 may include a color resist material such as a dye, a pigment, or another suitable material. In addition, the color of the light filter layer 170 may match the corresponding light conversion element 150. For example, the light conversion element 150 and the light filter layer 170 corresponding to the same opening 120S may both be red or both be green. The light filter layer 170 may also include a yellow color resist and overlap with the green or red light conversion element 150. In other embodiments, the stacking order of the protective layer 160 and the light filter layer 170 may be adjusted such that the light filter layer 170 is located between the protective layer 160 and the light conversion element 150. The light filter layer 170 may be partially disposed in the opening 120S defined by the insulating layer 120. Moreover, in other embodiments, the protective layer 160 may be omitted. In other embodiments, another protective layer (not shown) may be further formed on the light filter layer 170 such that the light filter layer 170 is disposed between the two protective layers.

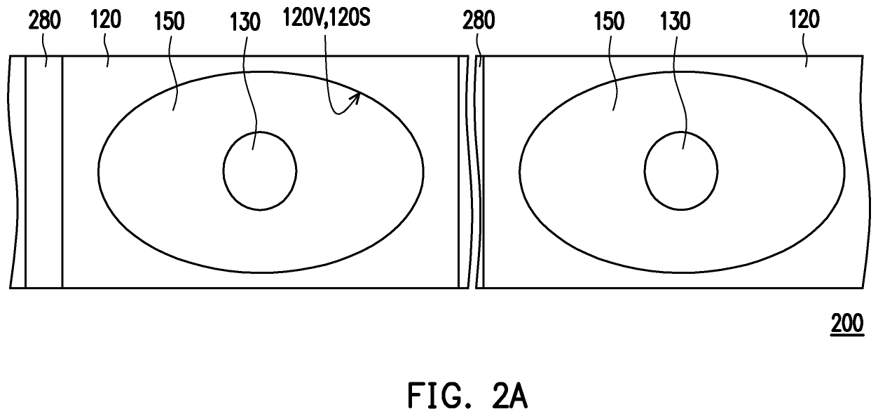

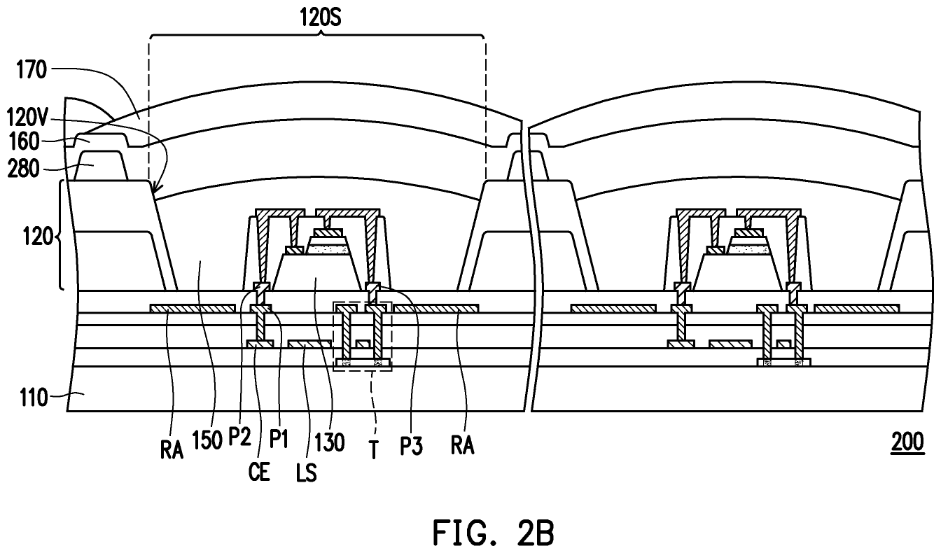

FIG. 2A is a schematic top view showing an electronic device according to another embodiment of the disclosure, and FIG. 2B is a schematic cross-sectional view showing the electronic device of FIG. 2A. Referring to FIG. 2A and FIG. 2B at the same time, an electronic device 200 includes a substrate 110, an insulating layer 120, a light-emitting unit 130, a light conversion element 150, a protective layer 160, a light filter layer 170, and a light shielding layer 280. Specifically, the substrate 110, the insulating layer 120, the light-emitting unit 130, the light conversion element 150, the protective layer 160, and the light filter layer 170 in the electronic device 200 of FIG. 2A and FIG. 2B are similar to those of the electronic device 100 of FIG. 1G, so the details of the structures, properties, arrangement relationships, manufacturing methods, and alternative embodiments of the above units will not be repeatedly described herein. For example, the material of the light shielding layer 280 may include a black matrix, a reflective material, or a combination thereof but is not limited thereto. In addition, units such as an active unit T, a common line CE, a light shielding layer LS, a reflective layer RA, a connection electrode P1, a connection electrode P2, and a connection electrode P3 may be provided on the substrate 110 of the present embodiment. As can be seen from FIG. 2A, in the present embodiment, the light conversion element 150 may surround the light-emitting unit 130, but is not limited thereto. In the present embodiment, the electronic device 200 may further include the light shielding layer 280, and the light shielding layer 280 may be disposed on the insulating layer 120. Specifically, in the case where the insulating layer 120 of the electronic device 200 defines a plurality of openings 120S, the electronic device 200 may have a plurality of light filter layers 170, where adjacent light filter layers 170 may be partially overlapped, and the light shielding layer 280 may be correspondingly disposed at the intersection of two adjacent light filter layers 170. The light shielding layer 280 may reflect or absorb light, but is not limited thereto. Disposing the light shielding layer 280 can reduce mutual interference of the light emitted by the light conversion elements 150 in two adjacent openings 120S, which helps to improve the light emission effect. In addition, the capping layer 140 in the electronic device 100 may be omitted in the electronic device 200. Accordingly, the light conversion element 150 may be in contact with the sidewall of the insulating layer 120, but is not limited thereto. In other embodiments, other film layers may be disposed between the light conversion element 150 and the insulating layer 120.

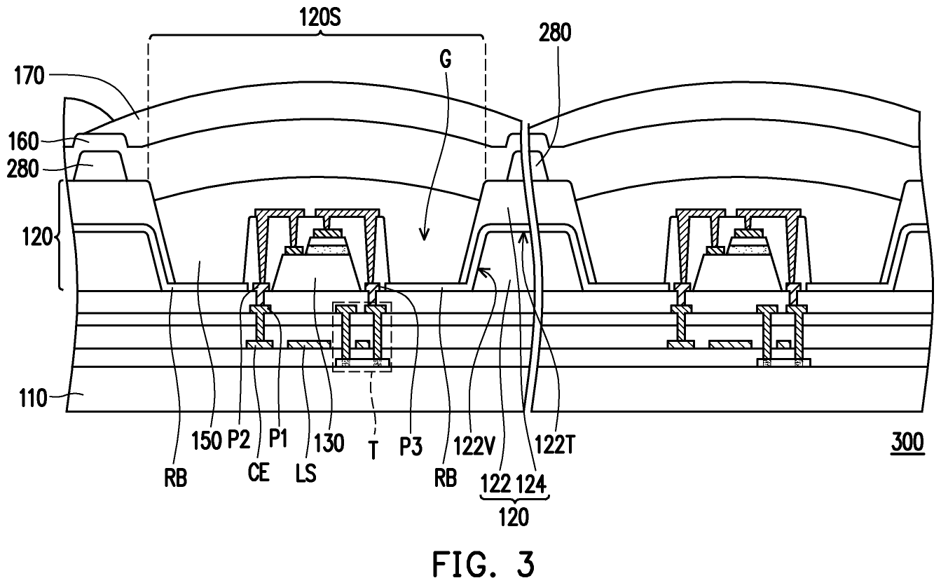

FIG. 3 is a schematic cross-sectional view showing an electronic device according to another embodiment of the disclosure. Referring to FIG. 3, an electronic device 300 is substantially similar to the electronic device 200, and the electronic device 300 may include a substrate 110, an insulating layer 120, a light-emitting unit 130, a light conversion element 150, a protective layer 160, a light filter layer 170, and a light shielding layer 280. Therefore, the details of the structures, properties, arrangement relationships, manufacturing methods, and alternative embodiments of the above units will not be repeatedly described herein. Specifically, units such as an active unit T, a common line CE, a light shielding layer LS, a connection electrode P1, a connection electrode P2, and a connection electrode P3 may be provided on the substrate 110 of the electronic device 300, and the electronic device 300 further includes a reflective layer RB.

The material of the reflective layer RB may include a metal or a Bragg reflection structure, but is not limited thereto. The metal material may include aurum, silver, copper, aluminum, or another suitable metal. The Bragg reflection structure may be a multi-layer stack structure, which may be formed by stacking a plurality of insulating layer of different refractive indices. In the present embodiment, the reflective layer RB may be located at least in a gap G between the insulating layer 120 and the light-emitting unit 130. The reflective layer RB may, for example, reflect the light from the light conversion element 150, so that the light is emitted away from the substrate 110. Therefore, the arrangement of the reflective layer RB helps to improve the light utilization efficiency. In addition, the reflective layer RB of the present embodiment may be further disposed on a sidewall 122V of a first sub-layer 122, or even on a top surface 122T of the first sub-layer 122. A second sub-layer 124 of the insulating layer 120 may be disposed on the first sub-layer 122 and the reflective layer RB. Therefore, the reflective layer RB may be partially covered by the second sub-layer 124. In other words, the reflective layer RB may be partially disposed between the first sub-layer 122 and the second sub-layer 124. However, in other embodiments, it is possible that the reflective layer RB is not disposed on the first sub-layer 122, but is disposed only in the gap G between the insulating layer 120 and the light-emitting unit 130. Since the reflective layer RB can provide an effect similar to that of the reflective layer RA of the foregoing embodiments, the reflective layer RA may be omitted on the substrate 110 of the present embodiment.

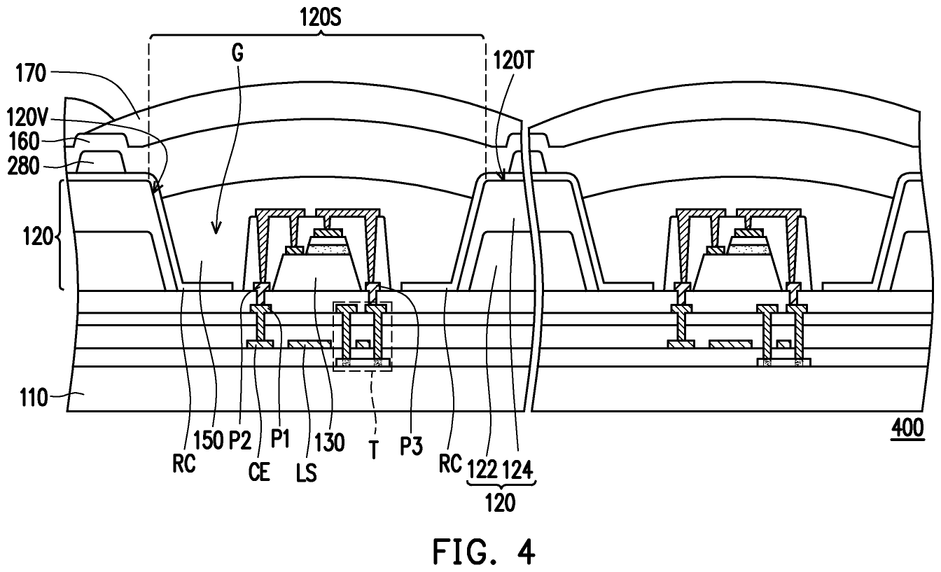

FIG. 4 is a schematic cross-sectional view showing an electronic device according to still another embodiment of the disclosure. Referring to FIG. 4, an electronic device 400 is substantially similar to the electronic device 300, and the electronic device 400 may include a substrate 110, an insulating layer 120, a light-emitting unit 130, a light conversion element 150, a protective layer 160, a light filter layer 170, and a light shielding layer 280. Therefore, the details of the structures, properties, arrangement relationships, manufacturing methods, and alternative embodiments of the above units will not be repeatedly described herein. Specifically, units such as an active unit T, a common line CE, a light shielding layer LS, a connection electrode P1, a connection electrode P2, and a connection electrode P3 may be provided on the substrate 110 of the electronic device 400, and the electronic device 400 further includes a reflective layer RC. The electronic device 400 of the present embodiment is substantially similar to the electronic device 300, and the difference between the two embodiments mainly lies in the arrangement position of the reflective layer RC of the present embodiment. In the present embodiment, the reflective layer RC may include a metal reflective layer or a Bragg reflection structure. The reflective layer RC may be located in a gap G between the insulating layer 120 and the light-emitting unit 130. The reflective layer RC may be further disposed on a sidewall 120V of the insulating layer 120, and even on a top surface 120T of the insulating layer 120. The light shielding layer 280 may be disposed on the reflective layer RC.

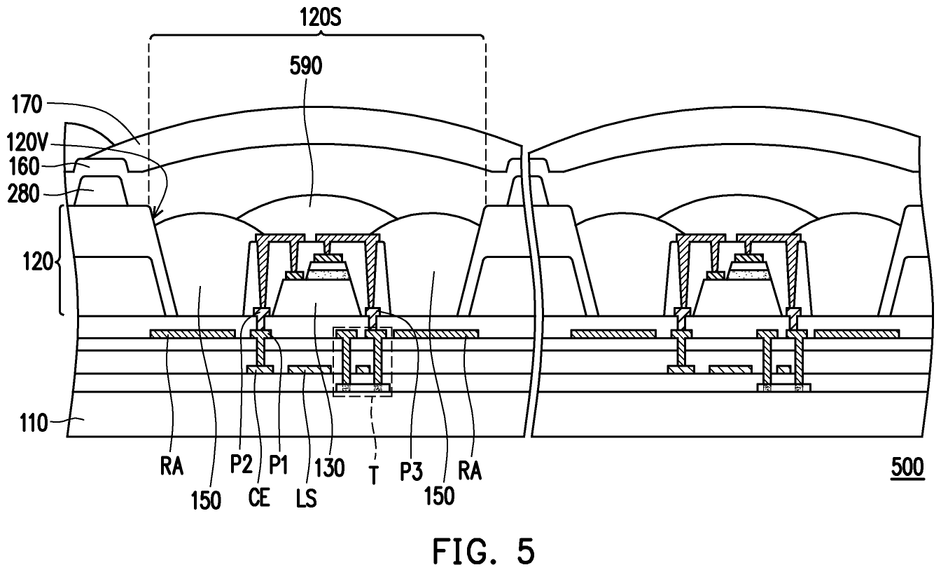

FIG. 5 is a schematic cross-sectional view showing an electronic device according to still another embodiment of the disclosure. Referring to FIG. 5, an electronic device 500 includes a substrate 110, an insulating layer 120, a light-emitting unit 130, a light conversion element 150, a protective layer 160, a light filter layer 170, a light shielding layer 280, and a light shielding layer 590. Specifically, the substrate 110, the insulating layer 120, the light-emitting unit 130, the light conversion element 150, the protective layer 160, the light filter layer 170, and the light shielding layer 280 in the electronic device 500 are similar to those of the electronic device 200 of FIG. 2B, so the details of the structures, properties, arrangement relationships, manufacturing methods, and alternative embodiments of the above units will not be repeatedly described herein. In addition, units such as an active unit T, a common line CE, a light shielding layer LS, a reflective layer RA, a connection electrode P1, a connection electrode P2, and a connection electrode P3 may be provided on the substrate 110 of the present embodiment. In the present embodiment, the electronic device 500 may further include the light shielding layer 590, and the light shielding layer 590 may be disposed on the light-emitting unit 130. In other words, the light-emitting unit 130 may be located between the light shielding layer 590 and the substrate 110. The light shielding layer 590 may include a white light shielding layer, a black light shielding layer, a metal light shielding layer, a Bragg reflection structure, another suitable light shielding layer, or a combination thereof, but is not limited to. In addition to shielding light, the light shielding layer 590 may also reflect light. In an embodiment, in the case where the light shielding layer 590 is a metal light shielding layer, an insulating layer or a dielectric layer may be disposed between the light shielding layer 590 and a connection electrode CLE (e.g., a portion of the capping layer 140 of FIG. 1G may be disposed between the light shielding layer 590 and the connection electrode CLE). By providing the light shielding layer 590, the light emitted by the light-emitting unit 130 may be laterally irradiated to the light conversion element 150 surrounding the light-emitting unit 130 in a higher proportion to improve the light conversion efficiency of the light conversion element 150.

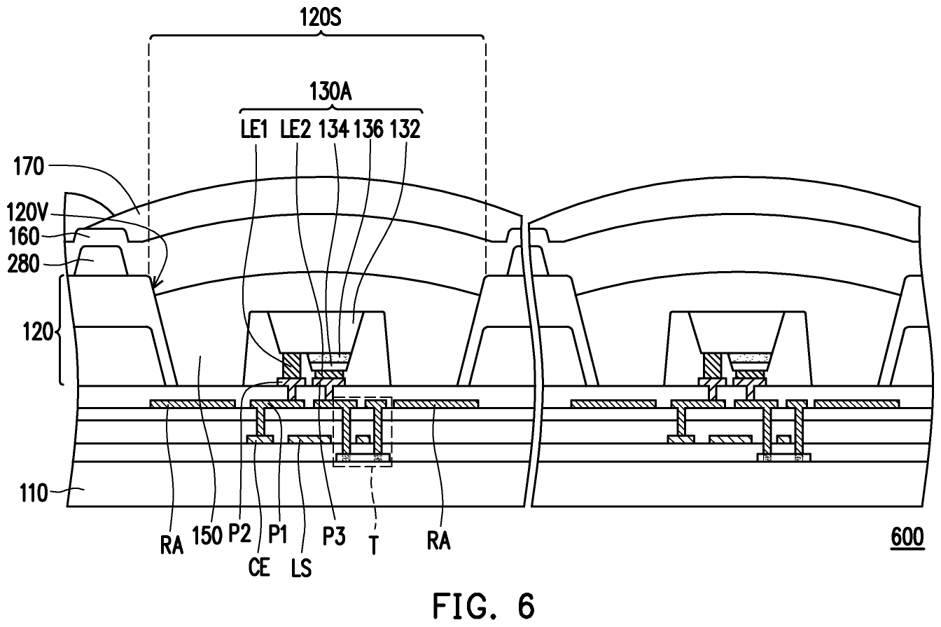

FIG. 6 is a schematic cross-sectional view showing an electronic device according to still another embodiment of the disclosure. Referring to FIG. 6, an electronic device 600 includes a substrate 110, an insulating layer 120, a light-emitting unit 130A, a light conversion element 150, a protective layer 160, a light filter layer 170, and a light shielding layer 280. Specifically, the substrate 110, the insulating layer 120, the light conversion element 150, the protective layer 160, the light filter layer 170, and the light shielding layer 280 in the electronic device 600 are similar to those of the electronic device 200 of FIG. 2B, so the details of the structures, properties, arrangement relationships, manufacturing methods, and alternative embodiments of the above units will not be repeatedly described herein. In addition, units such as an active unit T, a common line CE, a light shielding layer LS, a reflective layer RA, a connection electrode P1, a connection electrode P2, and a connection electrode P3 may be provided on the substrate 110 of the present embodiment. In the present embodiment, the structure of the light-emitting unit 130A is substantially the same as that of the light-emitting unit 130 shown in FIG. 1G or FIG. 2B, but the arrangement direction of the light-emitting unit 130A is different from that in the foregoing embodiments.

Specifically, the light-emitting unit 130A may include a first semiconductor layer 132, a second semiconductor layer 134, an active layer 136, a first electrode LE1, and a second electrode LE2. The active layer 136 is disposed between the first semiconductor layer 132 and the second semiconductor layer 134. The first electrode LE1 may be connected to the first semiconductor layer 132, and the second electrode LE2 may be connected to the second semiconductor layer 134. The first electrode LE1 and the second electrode LE2 may be located on a side of the stack structure formed by the first semiconductor layer 132, the second semiconductor layer 134, and the active layer 136 toward the substrate 110. In other words, the light-emitting unit 130A of the present embodiment is disposed on the substrate 110 in an inverted manner as compared with the foregoing embodiments. At this time, after the light-emitting unit 130A is disposed on the substrate 110, the first electrode LE1 and the second electrode LE2 are not exposed on the top surface but are disposed between the stack structure and the substrate 110.

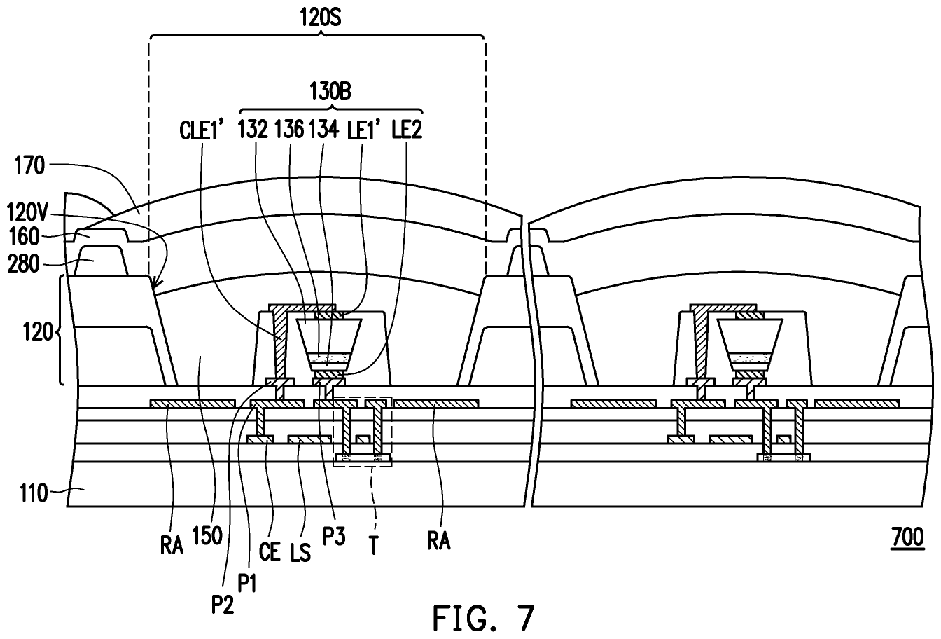

FIG. 7 is a schematic cross-sectional view showing an electronic device according to still another embodiment of the disclosure. Referring to FIG. 7, an electronic device 700 includes a substrate 110, an insulating layer 120, a light-emitting unit 130B, a light conversion element 150, a protective layer 160, a light filter layer 170, and a light shielding layer 280. Specifically, the substrate 110, the insulating layer 120, the light conversion element 150, the protective layer 160, the light filter layer 170, and the light shielding layer 280 in the electronic device 700 are similar to those of the electronic device 200 of FIG. 2B, so the details of the structures, properties, arrangement relationships, manufacturing methods, and alternative embodiments of the above units will not be repeatedly described herein. In addition, units such as an active unit T, a common line CE, a light shielding layer LS, a reflective layer RA, a connection electrode P1, a connection electrode P2, and a connection electrode P3 may be provided on the substrate 110 of the present embodiment. In the present embodiment, the structure of the light-emitting unit 130B is substantially the same as that of the light-emitting unit 130 shown in FIG. 1G or FIG. 2B, but the electrode arrangement of the light-emitting unit 130B is different from that in the foregoing embodiment.

Specifically, the light-emitting unit 130B may include a first semiconductor layer 132, a second semiconductor layer 134, an active layer 136, a first electrode LE1′, and a second electrode LE2. The active layer 136 is disposed between the first semiconductor layer 132 and the second semiconductor layer 134. The first electrode LE1′ may be connected to the first semiconductor layer 132, and the second electrode LE2 may be connected to the second semiconductor layer 134. The first electrode LE1′ and the second electrode LE2 are respectively located on two opposite sides of the stack structure formed by the first semiconductor layer 132, the second semiconductor layer 134, and the active layer 136. Accordingly, the first electrode LE1′ may be located on the side of the light-emitting unit 130B that is away from the substrate 110, and the second electrode LE2 may be located on the side of the light-emitting unit 130B that is close to the substrate 110. Therefore, the second electrode LE2 may be directly connected to the connection electrode P3 and the first electrode LE1′ may be connected to the connection electrode P2 on the substrate 110 via a connection electrode CLE1′. In other words, the light-emitting unit 130B may be a vertically configured light-emitting diode.

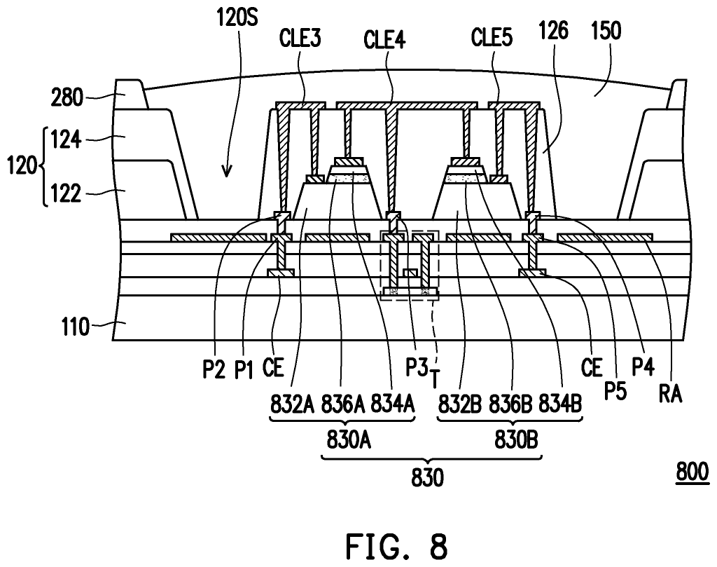

FIG. 8 is a schematic cross-sectional view showing an electronic device according to still another embodiment of the disclosure. Referring to FIG. 8, an electronic device 800 includes a substrate 110, an insulating layer 120, a light-emitting unit 830, a light conversion element 150, and a light shielding layer 280. Specifically, the substrate 110, the insulating layer 120, the light conversion element 150, and the light shielding layer 280 in the electronic device 800 are similar to those of the electronic device 200 of FIG. 2B. Units such as an active unit T, a common line CE, a reflective layer RA, a connection electrode P1, a connection electrode P2, and a connection electrode P3 may be provided on the substrate 110 of the present embodiment. The details of the structures, properties, arrangement relationships, manufacturing methods, and alternative embodiments of the above units will not be repeatedly described herein. In addition, the protective layer 160 and the light filter layer 170 of the foregoing embodiments may be selectively further disposed in the present embodiment.

Specifically, the light-emitting unit 830 of the present embodiment may include a first light-emitting diode 830A and a second light-emitting diode 830B. In addition, the structure of at least one of the first light-emitting diode 830A and the second light-emitting diode 830B may be similar to any one of the above light-emitting units 130, 130A, and 130B. In FIG. 8, the first light-emitting diode 830A and the second light-emitting diode 830B have a structure and an arrangement direction similar to those of the light-emitting unit 130, but are not limited thereto. In an embodiment, the colors of the light emitted by the first light-emitting diode 830A and the second light-emitting diode 830B may be the same or different.

In the present embodiment, the first light-emitting diode 830A and the second light-emitting diode 830B may be encapsulated by an encapsulating layer 126. The first light-emitting diode 830A includes a first semiconductor layer 832A, a second semiconductor layer 834A, and an active layer 836A disposed between the first semiconductor layer 832A and the second semiconductor layer 834A. The second light-emitting diode 830B includes a first semiconductor layer 832B, a second semiconductor layer 834B, and an active layer 836B disposed between the first semiconductor layer 832B and the second semiconductor layer 834B. In addition to the connection electrode P1 to the connection electrode P3, a connection electrode P4 and a connection electrode P5 are further disposed on the substrate 110, and the connection electrode P4 and the connection electrode P5 are similar to the connection electrode P1 and the connection electrode P2, moreover, are connected to the common line CE. In addition, the electronic device 800 further includes a connection electrode CLE3 to a connection electrode CLE5. The connection electrode CLE3 may connect the first semiconductor layer 832A to the connection electrode P2 on the substrate 110. The connection electrode CLE4 may connect both the second semiconductor layer 834A and the second semiconductor layer 834B to the connection electrode P3. The connection electrode CLE5 may connect the first semiconductor layer 832B to the connection electrode P4. In the present embodiment, the arrangement of the first light-emitting diode 830A and the second light-emitting diode 830B on the substrate 110 may be as shown in FIG. 1B. In addition, the manner in which the encapsulating layer 126 encapsulates the first light-emitting diode 830A and the second light-emitting diode 830B may be as shown in FIG. 1C to FIG. 1D. The material of the encapsulating layer 126 may be, for example, the same as that of the second sub-layer 124 of the insulating layer 120, but is not limited thereto. Moreover, at least one of the reflective layer RB, the reflective layer RC, the capping layer 140, the protective layer 160, and the light filter layer 170 described in the foregoing embodiments may be selectively applied in the present embodiment. It is noted that although FIG. 8 only shows two light-emitting units, more light-emitting units (e.g., three or four) may be disposed in one opening 120S according to the actual requirements, but the disclosure is not limited thereto.

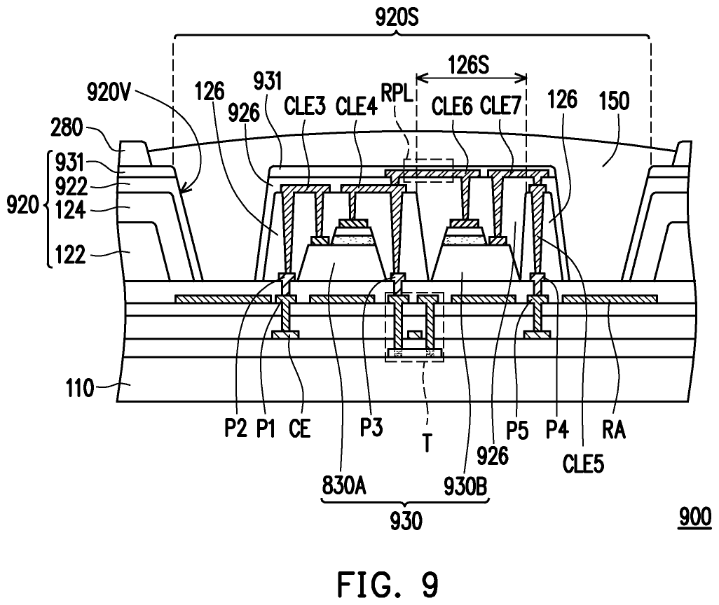

FIG. 9 is a schematic cross-sectional view showing an electronic device according to still another embodiment of the disclosure. Referring to FIG. 9, an electronic device 900 includes a substrate 110, an insulating layer 920, a light-emitting unit 930, a light conversion element 150, and a light shielding layer 280. Units such as an active unit T, a common line CE, a reflective layer RA, a connection electrode P1, a connection electrode P2, a connection electrode P3, and a connection electrode P4 may be provided on the substrate 110 of the present embodiment. Specifically, the substrate 110 and the light shielding layer 280 in the electronic device 900 are similar to the substrate 110 and the light shielding layer 280 of FIG. 8. The details of the structures, properties, arrangement relationships, manufacturing methods, and alternative embodiments of the above units will not be repeatedly described herein. In the present embodiment, the insulating layer 920 may include a first sub-layer 122, a second sub-layer 124, and a third sub-layer 922. The first sub-layer 122 and the second sub-layer 124 are substantially similar to the insulating layer 120 of the foregoing embodiments and thus will not be repeatedly described herein. In the present embodiment, the electronic device 900 may selectively further include a protective layer 931. A portion of the protective layer 931 is stacked on the third sub-layer 922 to form a portion of the insulating layer 920, and another portion of the protective layer 931 is located on the light-emitting unit 930, but the disclosure is not limited thereto. In addition, the light-emitting unit 930 of the present embodiment includes a first light-emitting diode 830A and a second light-emitting diode 930B, and the first light-emitting diode 830A is substantially similar to the first light-emitting diode 830A of the foregoing embodiment and thus will not be repeatedly described herein.

In the present embodiment, the manufacturing methods of the first sub-layer 122, the first light-emitting diode 830A, and the second sub-layer 124 are as described in the above steps of FIG. 1B to FIG. 1D. Therefore, the second sub-layer 124 may be disposed on the first sub-layer 122. An encapsulating layer 126 may be disposed on the first light-emitting diode 830A. A portion of a connection electrode CLE3, a portion of a connection electrode CLE4, and a portion of a connection electrode CLE5 may be disposed on the encapsulating layer 126. A portion of the connection electrode CLE3 may extend into the encapsulating layer 126 to be connected to the connection electrode P2. A portion of the connection electrode CLE4 may extend into the encapsulating layer 126 to be connected to the connection electrode P3. A portion of the connection electrode CLE5 may extend into the encapsulating layer 126 to be connected to the connection electrode P4. In the present embodiment, the encapsulating layer 126 may have an opening 126S. For example, the opening 126S may be located between the first light-emitting diode 830A and the connection electrode CLE5.

The second light-emitting diode 930B may be disposed in the opening 126S, and, in the present embodiment, the third sub-layer 922 and an encapsulating layer 926 may be formed after the second light-emitting diode 930B is disposed on the substrate 110. The third sub-layer 922 may be disposed on the second sub-layer 124. The encapsulating layer 926 may be disposed on the second light-emitting diode 930B and may, for example, encapsulate the second light-emitting diode 930B, but is not limited thereto. The electronic device 900 may further include a connection electrode CLE6 and a connection electrode CLE7. A portion of the connection electrode CLE6 and the connection electrode CLE7 may be disposed on the encapsulating layer 926. A portion of the connection electrode CLE6 and the connection electrode CLE7 may extend into the encapsulating layer 926, but is not limited thereto. The connection electrode CLE6 may be connected to the second light-emitting diode 930B and the connection electrode CLE4, and the connection electrode CLE7 may be connected to the second light-emitting diode 930B and the connection electrode CLE5. In addition, the insulating layer 920 of the electronic device 900 may further include a protective layer 931. A portion of the protective layer 931 may be selectively disposed on the third sub-layer 922, and a portion of the protective layer 931 may be disposed on the connection electrode CLE6 and/or the connection electrode CLE7 to protect the connection electrode CLE6 and the connection electrode CLE7. A sidewall 920V of the insulating layer 920 may be composed of a sidewall of the third sub-layer 922 and/or a sidewall of the protective layer 931, and the light-emitting unit 930 may be located in an opening 920S surrounded by the sidewall 920V.

A portion of the connection electrode CLE6 may be regarded as a repair line segment RPL. When it is necessary to disconnect the first light-emitting diode 830A from the second light-emitting diode 930B, the repair line segment RPL may be cut to achieve the repairing effect. In some embodiments, after the first light-emitting diode 830A is disposed on the substrate 110, it may be detected whether the first light-emitting diode 830A normally emits light. If the first light-emitting diode 830A can normally emit light, the second light-emitting diode 930B may be omitted. Therefore, it is possible that the opening 126S of the encapsulating layer 126 is not provided with the second light-emitting diode 930B but is directly filled with the encapsulating layer 926 or is filled with the material of the light conversion element 150. In some embodiments in which the second light-emitting diode 930B is not disposed in the opening 126S of the encapsulating layer 126, the protective layer 931 may be omitted. In other embodiments, if it is found after detection that the first light-emitting diode 830A cannot normally emit light, the second light-emitting diode 930B may be disposed in the opening 126S as shown in FIG. 9. In addition, in some embodiments, it is possible that the first light-emitting diode 830A is not detected before the second light-emitting diode 930B is disposed, but is detected only after the second light-emitting diode 930B is disposed on the substrate 110. At this time, if a defective second light-emitting diode 930B is found, the repair line segment RPL may be cut to achieve the repairing effect. The repair line segment RPL may be cut by laser cutting, for example, but is not limited thereto. Moreover, the arrangement directions and structural types of the various light-emitting units of the foregoing embodiments may all be selectively applied in the present embodiment, and at least one of the reflective layer RB, the reflective layer RC, the capping layer 140, the protective layer 160, and the light filter layer 170 described in the foregoing embodiments may be selectively applied in the present embodiment.

According to the above, in the electronic device of the embodiments of the disclosure, both the light-emitting unit and the light conversion element are disposed in the opening of the insulating layer. Accordingly, the light conversion element is not limited to be disposed at a height greater than that of the light-emitting unit, which helps to reduce the thickness of the electronic device. In addition, the light conversion element may surround the light-emitting unit and may be irradiated and excited by the lateral light of the light-emitting unit to emit a light emission wavelength. Such an arrangement contributes to increasing the light-emitting surface of the electronic device and reducing the concentration of the light-emitting area. Accordingly, the electronic device of the embodiments of the disclosure has improved light emission effect.

It will be apparent to those skilled in the art that various modifications, variations, and combinations can be made to the disclosed embodiments without conflicting with or departing from the scope or spirit of the disclosure. In view of the foregoing, it is intended that the disclosure covers modifications and variations provided that they fall within the scope of the following claims and their equivalents.

What is claimed is:

1. An electronic device, comprising:
a substrate;
an insulating layer, disposed on the substrate, and comprising an opening and a sidewall surrounding the opening;
a light-emitting unit, disposed in the opening; and
a light conversion element, disposed in the opening,
wherein a height of the sidewall is greater than or equal to a height of the light conversion element.

2. The electronic device according to claim 1, wherein the light conversion element encompasses the light-emitting unit.

3. The electronic device according to claim 1, wherein the insulating layer is multi-layer.

4. The electronic device according to claim 1, wherein the light-emitting unit comprises at least two light-emitting diodes.

5. The electronic device according to claim 1, further comprising a reflective layer disposed between the substrate and the light conversion element.
